(19) United States
(12) Patent Application Publication
(10) Pub. No.: US 2011/0290638 A1
(43) Pub. Date: Dec. 1, 2011

(54) SPUTTER DEVICE AND METHOD OF MANUFACTURING MAGNETIC STORAGE MEDIUM

(75) Inventors: Hiroshi Torii, Tokyo (JP); Ge Xu, San Jose, CA (US)

(73) Assignee: CANON ANELVA CORPORATION, Kawasaki-shi (JP)

(21) Appl. No.: 13/168,560

(22) Filed: Jun. 24, 2011

Related U.S. Application Data
(63) Continuation of application No. PCT/JP2009/071645, filed on Dec. 25, 2009.

(30) Foreign Application Priority Data
Dec. 26, 2008 (JP) 2008-334095

(51) Int. Cl. C23C 14/34

(52) U.S. Cl. 204/192.15; 204/298.15; 204/298.06; 204/298.08

(57) ABSTRACT

The present invention provides a sputter device and a method of manufacturing a magnetic storage medium capable of forming a buried layer with higher production efficiency in manufacturing a magnetic recording medium. In an embodiment of the present invention, cathodes in opposition to each other with a substrate (201) sandwiched in between are arranged and the phase of high-frequency power to be applied to each cathode is made the same. At this time, it is preferable to reduce the distance between each cathode and the substrate (201). Further, it is also preferable to perform deposition of a buried layer while attracting positive ions in plasma to the substrate (201) by an attracting electric field.

### CROSS-REFERENCES TO RELATED APPLICATIONS

This application is a continuation application of International Application No. PCT/JP2009/071645, filed Dec. 25, 2009, which claims the benefit of Japanese Patent Application No. 2008-334095, filed Dec. 26, 2008. The contents of the aforementioned applications are incorporated herein by reference in their entities.

### TECHNICAL FIELD

The present invention relates to a sputter device and a method of manufacturing a magnetic storage medium, and in more detail, to a sputter device and a method of manufacturing a magnetic storage medium for burying a predetermined material in a concave part in a layer (for example, a recording layer) in which concave/convex parts are formed.

### BACKGROUND ART

Conventionally, as a scheme for burying a pattern frequently used for semiconductor devices, a scheme is used, in which a target and a substrate are separated, only ionized sputter particles are attracted by a substrate bias, and they are caused to enter in a direction perpendicular to the substrate. According to this scheme, it is possible to improve bottom coverage. However, by such a scheme, when a recording layer having a concave/convex pattern is formed on a substrate, there may be a case where a difference in level in the pattern is not relaxed because films are deposited also on the top (convex part) side of the pattern more than those on the bottom (concave part) side.

Because of this, in a magnetic recording medium for which flattening is indispensable, such as BPM (Bit Patterned Media) and DTM (Discrete Track Media), films are deposited thick once and etching is performed using an etching means, such as IBE (Ion Beam Etching) and RIE (Reactive Ion Etching) (see Patent Document 1).

[Patent Document 1] Japanese Patent Laid-Open No. 2005-235357

### SUMMARY OF INVENTION

However, when the difference in level of the film surface in a concave/convex pattern formed in a recording layer etc. is large, it is necessary to repeat several times the cycle of forming a film to be buried in the concave part and etching for flattening, and therefore, reduction in production efficiency and a rise in device cost result.

The present invention has been made in view of such problems and an object thereof is to provide a sputter device and a method of manufacturing a magnetic storage medium capable of forming a buried layer with higher production efficiency.

In order to achieve the above-mentioned object, the present invention is a sputter device characterized by comprising a vacuum vessel, two cathodes arranged in opposition to each other in the vacuum vessel and capable of generating plasma in a region between the two cathodes by supply of high-frequency power, and a phase adjustment mechanism capable of adjusting phases of high-frequency power outputs to be supplied to each of the two cathodes into the same phase, and by being configured such that a substrate holding mechanism to hold a substrate is disposed in the region between the two cathodes where plasma is generated.

Moreover, the present invention is a method of manufacturing a magnetic recording medium for performing deposition of a buried layer by the high-frequency sputtering method for a concave/convex pattern of a recording magnetic layer provided on a substrate, characterized by comprising the steps of disposing a substrate holding mechanism to hold a substrate having the recording magnetic layer in a region between two cathodes arranged in opposition to each other in a vacuum vessel and supporting a target and generating plasma on both surfaces of the substrate by introducing a discharge gas into the vacuum vessel and supplying high-frequency power in the same phase to the two cathodes, and in that the deposition of the buried layer is performed by the high-frequency sputtering method using sputter particles generated from the target by sputter using the plasma and ions of the discharge gas.

According to the present invention, it is possible to form flat films on both surfaces using high-frequency waves.

### BRIEF DESCRIPTION OF THE DRAWINGS

FIG. 1A is a schematic diagram for explaining principles of the present invention.

FIG. 1B is a schematic diagram for explaining principles of the present invention.

FIG. 2 is an outline configuration diagram of a sputter device according to an embodiment of the present invention.

FIG. 3 is a diagram showing an example of deposition according to an embodiment of the present invention.

FIG. 4 is a front view of a substrate holding mechanism according to an embodiment of the present invention.

FIG. 5 is a graph showing a relationship among process pressure, bias voltage, and deposition rate ratio according to an embodiment of the present invention.

FIG. 6 is a schematic diagram showing a deposition state when a buried material is deposited under each condition according to an embodiment of the present invention.

### DESCRIPTION OF EMBODIMENTS

In order to solve the above-mentioned problems, in the present invention, deposition of a buried layer is performed by supplying high-frequency power in the same phase to cathodes arranged in opposition to each other on both sides of a substrate at a predetermined interval to generate plasma on both surfaces of the substrate and by sputtering a target provided on both sides of the substrate. It is preferable for the above-mentioned predetermined interval to be 70 mm or less. It may also be possible to perform deposition of the above-mentioned buried layer by forming an attracting electric field to attract positive ions in the plasma into the substrate when sputtering the target and attracting the positive ions into the substrate by the attracting electric field.

It is possible to appropriately utilize the present invention in forming a buried layer of a recording magnetic layer in a magnetic recording medium (a layer buried in a concave part formed in a recording magnetic layer having concave/convex parts as in a concave/convex pattern). The structure and the constituent material of such a magnetic recording medium are not limited as long as it is a magnetic recording medium having a buried layer by the high-frequency sputtering method.

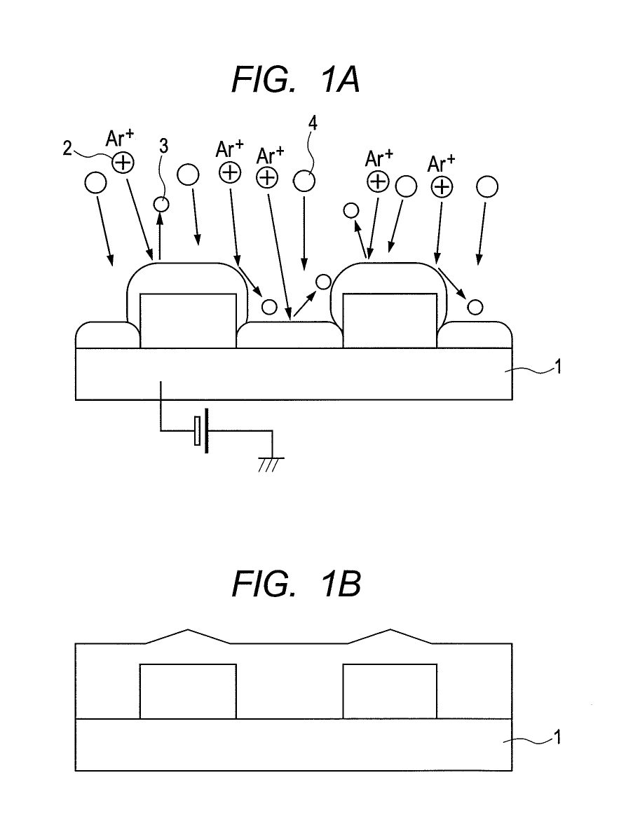

The formation of a buried layer in the present invention is explained using FIGS. 1A, 1B. As shown in FIG. 1A, when a substrate (pattern substrate) 1 on which a concave/convex pattern is formed in a magnetic recording layer and a cathode (not shown schematically) are put close to each other and a substrate bias is used, ions 2 of a discharge gas (for example Ar) as well as ionized sputter particles 4 are attracted onto the substrate 1. As a result of that, at the same time as film deposition, etching of the deposited film by sputter by gas ions also takes place. When the deposited film on the top side of the concave/convex pattern (for example, at the upper side in the diagram, such as the top of the convex part of the concave/convex pattern) is sputtered by ions, part (for example, particle) 3 of the etched film scatters into a space. On contrast to this, when the deposited film on the side surface or the bottom side of the concave/convex pattern (for example, at the lower side in the diagram, such as the wall surface and bottom surface of the concave part of the concave/convex pattern) is sputtered by ions, the part 3 of the etched film is deposited again on the side surface and the bottom side of the concave/convex pattern. As a result of that, only the deposited film on the top side of the concave/convex pattern is etched selectively and deposition is advanced in a state where film deposition occurs on the side surface and the bottom side of the concave/convex pattern. As a result of that, the film surface finally formed has a shape more flattened than the original concave/convex pattern as shown in FIG. 1B.

As described above, it is necessary to sufficiently supply gas ions (for example, the ions 2 of the discharge gas) for etching to the concave/convex pattern provided on the substrate and at the same time, to increase the proportion of the gas ions (for example, the ionized sputter particles 4) corresponding to the deposition particles that reach the concave/convex pattern provided on the substrate, in order to implement selective etching by ions on the surface of the concave/convex pattern of the substrate, in particular, on the top side of the concave/convex pattern.

In order to supply gas ions to the concave/convex pattern provided on the substrate, it is effective to reduce the distance between the cathode and the substrate and attract the gas ions generated by the target discharge on the cathode by the substrate bias. In order to increase the proportion of the gas ions (deposition particle gas ions) corresponding to the deposition particles, the sputter deposition by high-frequency waves is most suitable.

However, the reduction in the distance between the cathode of the high-frequency discharge and the substrate leads to mutual interference between the high-frequency waves of both the cathodes. Because of this, in order to solve this problem, in the present invention, a mechanism to control the phase of the high-frequency power output to be supplied to the cathode is provided and thereby the phase of the high-frequency power source provided on both sides of the substrate is controlled and thus the plasma distribution is made uniform and the deposition distribution is improved.

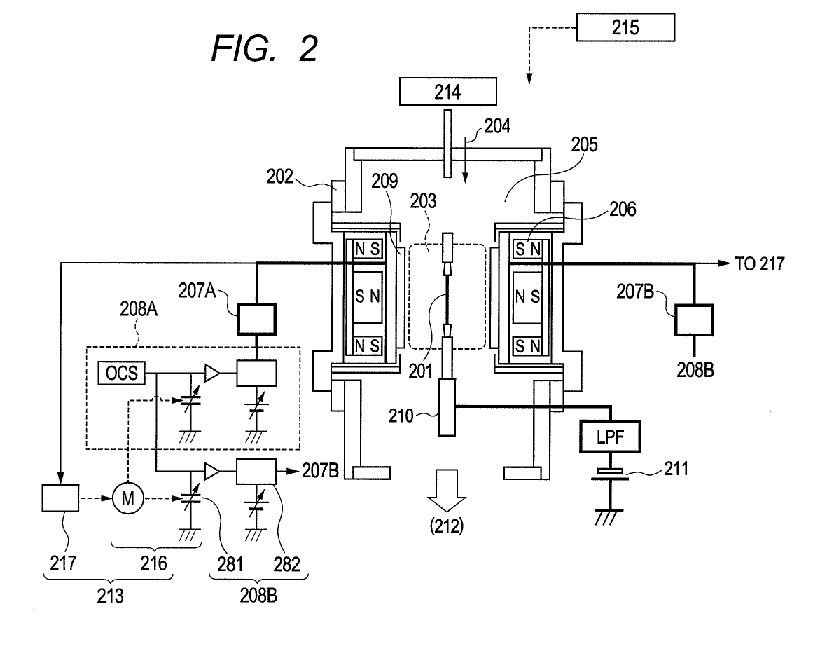

FIG. 2 shows an outline configuration of an embodiment of a sputter device suitable for embodying the present invention. The sputter device in FIG. 2 is controlled by a control device 215 and has a configuration in which a pair of cathodes for high-frequency discharge is installed in opposition to each other in a vacuum vessel 205. Each cathode has a target support surface to support a target 209. To each cathode, high-frequency power sources 208A, 208B, are connected independently of each other via matching devices 207A, 207B. On the rear surface of each cathode, a magnet mechanism 206 to apply a magnetic field is disposed. At least the inner wall surface of the vacuum vessel 205 is configured to function as a ground electrode and a discharge 203 is caused to occur by the introduction of a discharge gas into between each cathode and the inner wall surface from a gas introduction system 214. The pressure in the vacuum vessel 205 can be controlled by an exhaust means 212 and introduction 204 of a discharge gas etc. from the gas introduction system 214. A substrate 201 having a concave/convex pattern in which a buried layer is formed is transferred into the vacuum vessel 205 by a transfer mechanism, not shown schematically, in a state where the substrate is supported by a substrate holding mechanism 210 and stops at an intermediate position between both cathodes. That is, the substrate holding mechanism 210 is disposed in a predetermined position in opposition to the target 209 on the cathode in the vacuum vessel 205. As described above, the sputter device in FIG. 2 is configured so as to dispose the substrate holding mechanism 210 between the two cathodes. The substrate holding mechanism 210 is configured so that a bias voltage that can be utilized to form an attracting electric field is applied to the substrate 201 by a bias power source 211.

The distance between the cathode and the substrate placed on the substrate holding mechanism 210 is set so that the distance from the surface of the target 209 to the substrate surface (hereinafter, also referred to as “T/S value”) is not less than 20 mm and not more than 70 mm, or preferably, not more than 40 mm. Due to this, it is possible to uniformly supply ions generated when the discharge gas introduced from the gas introduction system 214 is turned into plasma to the surface to be processed of the substrate and to promote etching of the deposited film by the ions. It may also be possible to set the distance described above by adjusting the thickness of a cathode spacer 202 provided between the cathode and the vacuum vessel 205. The diameter of the cathode or the substrate is not limited in particular in the present invention and it is possible to appropriately use a disc-shaped target having a diameter greater than that of the disc-shaped substrate. For example, it is possible to use a substrate having a diameter of about 40 to 100 mm for a target having a diameter of 164 mm.

The high-frequency power sources 208A, 208B supply high-frequency power (for example, 13.56 MHz to 100 MHz) to the cathode. By using the high-frequency power source, it is possible to increase the ionization rate of the discharge gas and to increase the etching rate by the ions of the discharge gas. The magnitude of the supplied power is not limited in particular and for example, may be set to 100 W to 500 W. The cathodes on both sides are connected to the different high-frequency power sources respectively via the matching devices. The matching device is a matching device to match the input impedance to the cathode with the output impedance on the high-frequency power source side and includes a variable impedance element, such as a variable capacitor and variable inductor, for example.

The vacuum vessel is grounded and due to this, a discharge is caused to occur between the vacuum vessel and the cathode by the introduction 204 of the discharge gas using the vacuum vessel as a ground electrode.

A phase adjuster (phase adjustment mechanism) 213 has a phase difference detection unit 217 that detects each phase (in the diagram, the phase of potential on each transmission path between each cathode and each matching device) of the voltage (high-frequency power output) supplied to the cathode on both sides of the substrate holding mechanism 210 and detects its phase difference and a phase adjustment unit 216 that makes the phases of the power (high-frequency power outputs) to be supplied to the two cathodes into the same phase (phase difference 0°±45°) by controlling each of the high-frequency power sources 208A, 208B when the phases of the power output to both the cathodes are different. In the example in FIG. 2, when an output signal of a predetermined frequency of an oscillation circuit OCS is output to a power supplier 282 via a variable capacitor 281, the variable capacitor 281 is adjusted into a predetermined capacitance according to the phase difference. In FIG. 2, symbol M represents a motor to mechanically adjust the capacitance of the variable capacitor 281. The power supplier 282 includes a power amplification circuit, a band pass filter, etc., and supplies a high-frequency signal the phase of which is adjusted to the cathode after converting it into a predetermined high-frequency signal.

For example, when the phases of power to be supplied to the two cathodes are made opposite to each other, a discharge is caused to occur between the two cathodes because the distance between the substrate 201 and the target 209 is set to a comparatively short distance as described above, and therefore, plasma exists in a comparatively limited region. On the contrary to this, when the phases of power to be supplied to the two cathodes is made the same, a discharge is caused to occur between the substrate 201 and the sidewall of the grounded vacuum vessel 205, and the cathode, and plasma is formed in a region larger than that in the case where the phases are made opposite, and therefore, in the region in the vicinity of the substrate, the plasma density becomes uniform.

The adjustment of phases is made between an interval of deposition processing, however, it may also be made during the period of deposition processing.

By means of the magnet mechanism 206 provided on the back side of the cathode, it is possible to form a magnetic field in the vacuum vessel, which is horizontal with the target surface and perpendicular to the electric field for forming plasma. Due to this magnetic field, plasma is confined to the target surface in a high density and a magnetron discharge is caused to occur. The magnet mechanism 206 is not an indispensable component in the present invention, however, by causing a magnetron discharge on both sides of the substrate, it is possible to further increase the proportion of the discharge gas ions that reach the substrate.

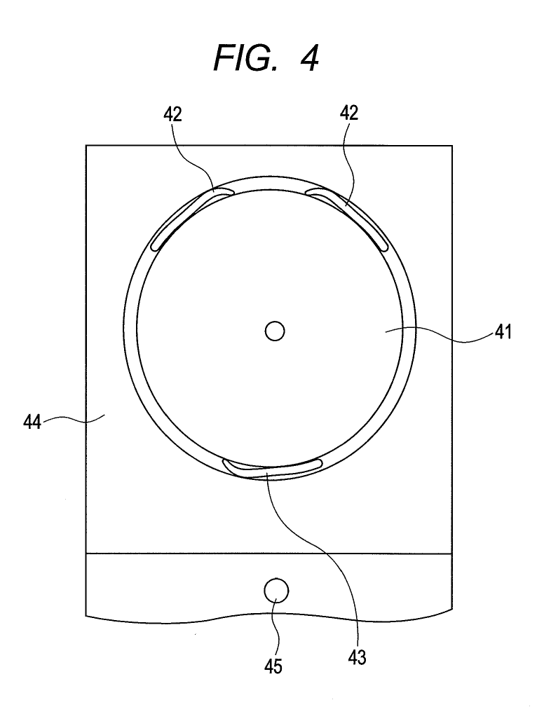

As shown in the front view in FIG. 4, the substrate holding mechanism 210 includes a substrate body 44 having conductive support claws 42, 43 that support a substrate 41 from the lateral side and a connection terminal 45 that receives the supply from the bias power source outside the vacuum vessel and supplies the bias voltage to the support claws 42, 43. Due to the configuration of the substrate holding mechanism 210, it is made possible to apply the bias voltage to the substrate 201 as well as to support the substrate 201. In the present embodiment, a direct-current bias voltage is applied. As a bias voltage, an alternating-current voltage may be applied or a pulse-shaped direct-current voltage may be applied. The magnitude of the bias voltage can be set to, for example, 100 V to 400 V and by applying a comparatively large voltage, it is possible to increase the proportion of the discharge gas ions on the substrate surface. An LPF (Low-pass filter) is a filter to prevent a high-frequency output for discharge from entering the bias power source side.

The gas introduction system 214 is provided so as to introduce a discharge gas (for example, Ar) from the top of the vacuum vessel 205 and the exhaust means 212 (cryopump, turbo molecular pump, etc.) is provided at the lower part to exhaust the interior of the sputter device. Due to this, it is possible to keep the pressure at the time of sputter at, for example, 1 Pa to 10 Pa. By keeping a comparatively high pressure, it is possible to increase the plasma density of the discharge gas and to promote etching by ionization of the discharge gas.

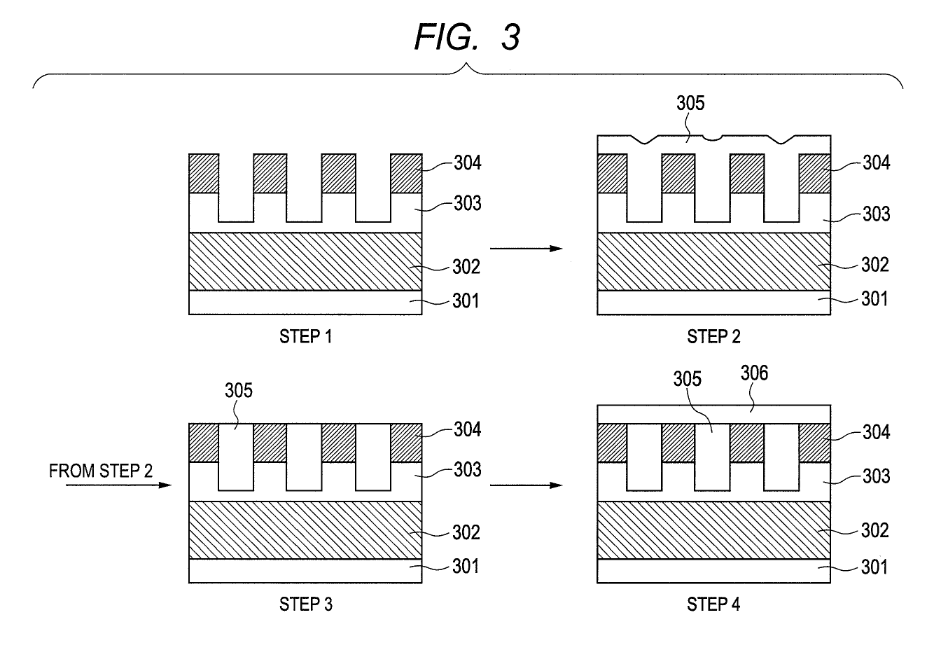

FIG. 3 shows an example of deposition of DTM as an example of deposition using the device with the above-mentioned configuration to manufacture a magnetic recording medium.

A stacked layer body in step 1 in FIG. 3 is on the way of processing into DTM and on a substrate 301, a soft magnetic layer 302, a foundation layer 303, and a recording magnetic layer 304 are formed. As the substrate 301, for example, a 2.5 in. glass substrate or aluminum substrate can be used. The soft magnetic layer 302 is a layer that plays a role as a yoke of the recording magnetic layer 304 and is, for example, a soft magnetic material, such as an Fe alloy and Co alloy. The foundation layer 303 is a layer to cause the recording magnetic layer 304 to orient vertically and is, for example, a stacked layer body etc. of Ru and Ta. The recording magnetic layer 304 is a layer that is magnetized in a direction perpendicular to the substrate 301 and is, for example, a Co alloy etc. A pitch p (groove width+track width) at this time is, for example, 50 to 100 nm, the groove width is 20 to 30 nm, the aspect ratio (groove depth/groove width) is 0.12 to 1.2, and a thickness d of the recording magnetic layer 304 is, for example, 4 to 20 nm.

For this stacked layer body, a buried layer 305 is formed so as to fill the grove of the recording magnetic layer 304 by using the sputter device shown in FIG. 2, setting the T/S value to 70 mm or less, and making the high-frequency power to be supplied to the two cathodes into the same phase. The formation material of the buried layer 305 is, for example, Cr, Ti, Ta, Nb, Zr, W, Si, or a combination thereof, or a compound of these and other metal elements (for example, Co, Ni) and sputter is performed using a target containing these. Specifically, as the target, mention is made, for example, of CoTi, CoTa, CoNb, CoZr, CoW, CoSi, NiTi, NiTa, NiNb, NiZr, NiW, NiSi (composition ratio is arbitrary), etc. In the present embodiment, the sputter device with the above-mentioned configuration is used, and therefore, the concave/convex parts produced in the buried layer 305 can be reduced as shown in step 2 in FIG. 3.

After that, the excess buried layer 305 is removed by etching etc. and after the recording magnetic layer 304 is exposed (step 3 in FIG. 3), by forming DLC (diamond-like carbon) 306 (step 3 in FIG. 3), DTM is manufactured. As a method of removing the excess buried layer 305, the conventional method can be used and for example, by using a material with an etching rate higher than that of the recording magnetic layer 304 as the buried layer 305, it is possible to suppress the removal of the recording magnetic layer 304 and to flatten the buried layer 305. By using the sputter device in the present embodiment, it is possible to save labor and time to repeat etching etc. because the irregularities of the buried layer 305 can be suppressed.

The conditions may also be changed so that as the irregularities become smaller, the amount of etching is increased when, for example, removing the excess buried layer 305.

In the present invention, it is particularly preferable to form a buried material into a film by the high-frequency sputtering method under the conditions that the deposition rate ratio compared to that when the attracting electric field is not formed is 90% or less. Here, the deposition rate ratio compared to that when the attracting electric field is not formed is a ratio of the deposition rate when forming a film on a flat surface while forming the attracting electric field, to the deposition rate when forming a film on a flat surface under the same conditions without forming the attracting electric field, in forming a film using a deposition gas (for example, a gas including ionized deposition particles) and an etching gas (for example, a discharge gas). The deposition rate is on the basis of the film thickness of a film formed per unit time.

When the deposition rate ratio exceeds 90%, the attracting of the etching gas into the substrate by the attracting electric field becomes weak, the etching becomes insufficient, and the effect of flattening the film surface becomes slight. Under the condition of too large an amount of etching, there may be a case where the deposition efficiency is reduced and the film thickness distribution is reduced. Consequently, although not limited, it is preferable to select the deposition rate ratio from among the range of 55% to 75%.

In order to obtain the target deposition rate ratio, a deposition rate when forming a film using a buried material on the flat surface of the substrate in a state where the attracting electric field is not applied is found, a deposition rate when the attracting electric field is applied under the same deposition condition is found, and the ratio of these rates is calculated. If the target deposition rate ratio is not obtained by the above-mentioned operation, the deposition conditions are changed in a variety of ways so that the target deposition rate ratio is obtained. By using the deposition conditions with which the target deposition rate ratio is obtained as described above, a buried layer is actually formed.

It is possible to adjust the deposition rate ratio by one or more parameters selected from among the pressure in the vacuum vessel at the time of deposition (process pressure), the application condition of the attracting electric field, the distance between the substrate and the target, etc. Among these conditions, it is preferable to adjust the deposition rate ratio using both the bias voltage to be applied to the substrate to adjust the attracting electric field and the process pressure.

It is possible to use the high-frequency sputter device for forming a film on both sides according to the present invention also when forming the above-mentioned recording magnetic layer 304, the foundation layer 303, other etching stop layers, etc., in addition to the buried layer 305 and it is possible to form a film on both sides with high uniformity in film thickness by making the electric power to be supplied to the cathodes arranged on both sides of the substrate into the same phase.

As described above, in the present invention, high-frequency power in the same phase is supplied to the two cathodes arranged in opposition to each other, and therefore, even if the distance between the substrate and each of the cathodes is reduced (for example, 70 mm or less) to reduce the interval between the two cathodes, it is possible to suppress the high frequency waves supplied to the two cathodes from interfering with each other. Consequently, even if the distance between the two cathodes is reduced and high-frequency power is supplied to the cathodes, the interference of the high-frequency power can be suppressed, and therefore, it is possible to make uniform the plasma formed by the above-mentioned cathodes. Further, the high-frequency power can be used in a state where the above-mentioned interference is reduced, and therefore, it is possible to efficiently generate gas ions corresponding to the deposition particles.

Because of the above, according to the present invention, even when the difference in level of the surface is large in the concave/convex pattern formed in the recording magnetic layer, it is possible to make uniform the distribution of thickness of the film formed by the above-mentioned uniform plasma and to suppress the irregularities formed in the buried layer from occurring. Consequently, it is possible to make an attempt to flatten the buried layer without the need to repeat deposition of the buried layer and etching and to suppress the reduction in production efficiency and the rise in device cost.

### EXAMPLE 1

In Example 1, the sputter device shown in FIG. 2 was used and a film was formed on a 95 mm flat substrate. The deposition conditions were that the T/S value was 28 mm, the kind of discharge gas was argon, the flow rate of argon was 500 sccm, the pressure of the discharge gas was 5 Pa, the bias was not applied to the substrate, the cathode supply power frequency was 13.56 MHz, and the discharge power was 500 W. The target material was Cr.

TABLE 1

| | Phase difference 0° | | Phase difference 180° | |
|---|---|---|---|---|
| On 95 mm disc | A surface | B surface | A surface | B surface |
| Film thickness | 7.4 | 7.7 | 14.2 | 13.2 |
| distribution (%) | | | | |
| Deposition rate | 2.5 | 2.5 | 3.5 | 3.5 |
| (nm/kW · s) | | | | |

As a result of this, it has been found that when the phase difference between the high frequency waves to be supplied to both the cathodes is 0°, that is, in the state where they are in phase, the uniformity of the film thickness distribution on the substrate is more excellent and the deposition rate is somewhat lower compared to when the phases are opposite as shown in Table 1. This can be thought because the discharge between the cathodes spreads in the widest range and thereby the discharge distribution in the vicinity of the substrate becomes more uniform.

### EXAMPLE 2

In Example 2, the sputter device shown in FIG. 2 was used and films were formed on a DTM medium substrate on which a plurality of grooves with a pitch of 100 nm (groove width of 50 nm) and a depth of 20 nm was formed in the direction of the diameter with the T/S value as 100 mm (comparative example), 40 mm. The deposition conditions are that the kind of discharge gas is Ar, the pressure of the discharge gas is 9 Pa, 500 W high-frequency power of 13.56 MHz is supplied to the cathode, a direct-current voltage of −200 V is applied as a substrate bias, and the target material is Cr.

As a result, it has been found that the irregularities on the film surface after the deposition are more suppressed from occurring when the T/S value is set to 40 mm compared to when the condition of the T/S value is 100 mm.

### EXAMPLE 3

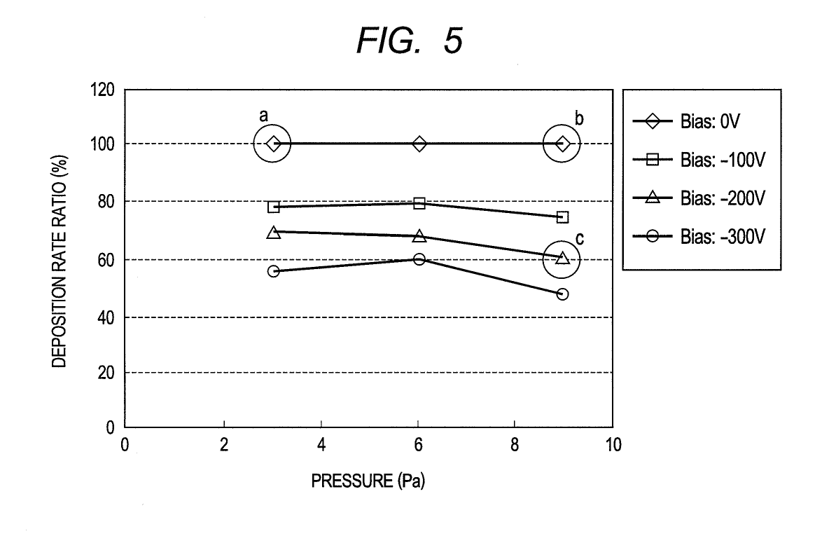

In Example 3, a relationship among the process pressure, the bias voltage, and the deposition rate ratio was examined. The sputter device (T/S value: 40 mm) shown in FIG. 2 was used and when the high-frequency power of 13. 56 MHz in the same phase was applied to both the cathodes, direct-current voltages of 0, −100 V, −200 V, −300 V were applied respectively to the substrate, and the target (target material: Cr) was formed into a film on a flat substrate surface under the condition of each process pressure, a relationship as shown in the graph in FIG. 5 was obtained. Here, the deposition rate ratio is a ratio of the deposition rate when a film is formed on a flat surface while applying a bias voltage, to the deposition rate when a film is formed on a flat surface without applying the bias voltage to the substrate under the same condition.

Under the same condition described above as to each deposition rate ratio, a film was formed on the DTM medium substrate on which a plurality of grooves with a pitch of 100 nm (groove width 50 nm) and a depth of 20 nm was formed in the direction of the diameter.

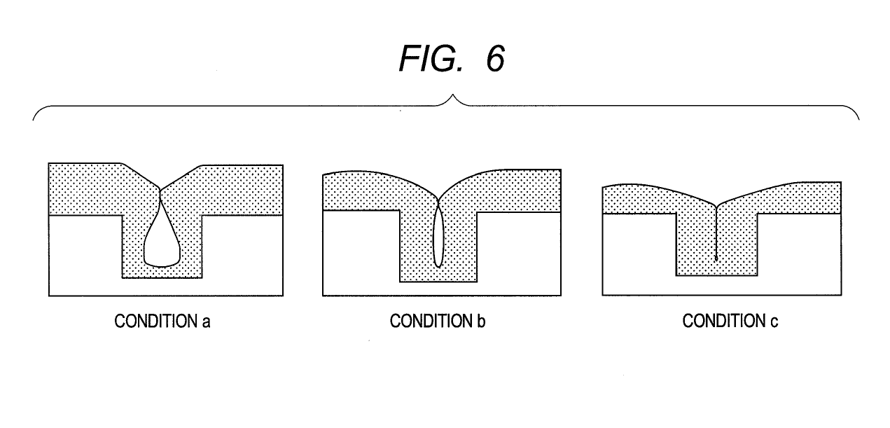

FIG. 6 schematically shows the deposition state under conditions a, b (condition a: process pressure 3 Pa, condition b: process pressure 9 Pa) that the deposition rate ratio is 100% and the bias voltage is not applied and condition c (process pressure 9 Pa, bias voltage −200 V) that the deposition rate ratio is 60%.

As shown in FIG. 6, under the condition a, it has been confirmed that a large void is formed because the amount of etching of the film in the convex part and the amount of attracting into the concave part are both small, and therefore, a large difference is produced between the amount of film formed in the convex part and the amount of film formed in the concave part. Under the condition b, it has been confirmed that a void is formed because the amount of etching of the film in the convex part is small even though the amount of attracting into the concave part is increased. On the contrary to this, under the condition c, it has been confirmed that no void is formed, the concave part is filled, and the difference in film thickness between the concave part and the convex part is suppressed small.

From the above, it is preferable for the deposition rate ratio to be 90% or less to sufficiently achieve the effect of the film surface flattening. Under the condition that the amount of etching is too much, there may be a case where not only the deposition efficiency but also the film thickness distribution becomes poor. Because of this, although not limited, it is preferable for the deposition rate ratio to be selected from the range of 55% to 75%.

In the present invention, when an attracting electric field is used as described above, it is preferable to set the deposition rate ratio to 90% or less or more preferably, 55% to 75%. What is important in the present invention is to make the phase of high-frequency power to be supplied to the two cathodes into the same phase when supplying high-frequency power to the two cathodes arranged in opposition to each other. By setting so, it is possible to suppress interference between high-frequency power and to form uniform plasma even if the two cathodes are arranged in close proximity, and therefore, it is possible to make an attempt to flatten a buried layer.

1. A sputter device comprising:
a vacuum vessel having an inner wall surface of which is grounded;
two cathodes arranged in opposition to each other in the vacuum vessel and capable of generating plasma in a region between the two cathodes by supply of high-frequency power outputs having a same frequency as each of the two cathodes;
a substrate holding mechanism capable of holding a substrate in the region between the two cathodes where plasma is generated; and
a phase adjustment mechanism configured to adjust phases of the high-frequency power outputs to be supplied to each of the two cathodes into the same phase during a period of deposition processing.

2. The sputter device according to claim 1, capable of manufacturing a magnetic recording medium having a recording magnetic layer formed in a concave/convex pattern and a buried layer located in a concave part of the concave/convex pattern and comprising:
a bias voltage applying means for applying a bias voltage to attract positive ions in the plasma into the substrate held by the substrate holding mechanism; and
a control means for supplying high-frequency power in the same phase to each of the two cathodes to generate plasma in the region and causing deposition of the buried layer to be performed while attracting positive ions in the plasma into the substrate held by the substrate holding mechanism by an attracting electric field formed by the bias voltage.

3. The sputter device according to claim 1,
wherein each of the two cathodes has a target support surface to support a target, and
wherein when the substrate holding mechanism is disposed in the region and the target is mounted on the target support surface, a distance between a surface of the substrate and a surface of the target is 70 mm or less.

4. The sputter device according to claim 1, further comprising two high-frequency power sources to supply the high-frequency power output to the cathode, wherein the phase adjustment mechanism has:
a phase difference detecting means for detecting the phase of the high-frequency power output to be supplied to each of the two cathodes; and
a phase adjusting means for controlling the two high-frequency power sources so that the phases of the high-frequency power outputs to be supplied to each of the two cathodes are the same phase when the phases of the high-frequency power outputs to be supplied to each of the two cathodes are different as a result of the detection of the phases.

5. A method of manufacturing a magnetic recording medium for performing deposition of a buried layer by a high-frequency sputtering method for a concave/convex pattern of a recording magnetic layer provided on a substrate, the method comprising the steps of:
disposing a substrate holding mechanism to hold the substrate having the recording magnetic layer in a region between two cathodes arranged in opposition to each other in a vacuum vessel having an inner wall surface of which is grounded and supporting a target; and
generating plasma on both surfaces of the substrate by introducing a discharge gas into the vacuum vessel and supplying high-frequency power having a same frequency and in a same phase to the two cathodes, wherein
the deposition of the buried layer is performed by the high-frequency sputtering method using sputter particles generated from the target by sputter using the plasma and discharge gas ions.

6. The method of manufacturing a magnetic recording medium according to claim 5, further comprising a step of applying a bias voltage to attract positive ions in the plasma into the substrate held by the substrate holding mechanism, wherein
the deposition of the buried layer is performed while attracting the sputter particles and the discharge gas ions into the substrate by an attracting electric field formed by the bias voltage.

7. (canceled)

8. The method of manufacturing a magnetic recording medium according to claim 5, wherein
a distance between a surface of the substrate and a surface of the target is 70 mm or less.
